(19) United States
(12) Patent Application Publication
(10) Pub. No.: US 2008/0173941 A1
(43) Pub. Date: Jul. 24, 2008

(54) ETCHING METHOD AND STRUCTURE IN A SILICON RECESS FOR SUBSEQUENT EPITAXIAL GROWTH FOR STRAINED SILICON MOS TRANSISTORS

(75) Inventors: Bei Zhu, Shanghai (CN); Paolo Bonfanti, Shanghai (CN); Hanming Wu, Shanghai (CN); Da Wei Gao, Shanghai (CN); John Chen, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Shanghai (CN)

(21) Appl. No.: 11/678,582

(22) Filed: Feb. 24, 2007

(30) Foreign Application Priority Data
Jan. 19, 2007 (CN) 200710036768.4

(51) Int. Cl. H01L 29/78; H01L 21/8238

(52) U.S. Cl. 257/344; 438/199; 257/E29.255; 257/E21.632

(57) ABSTRACT

A semiconductor integrated circuit device comprising a semiconductor substrate, e.g., silicon wafer, silicon on insulator. The device has a dielectric layer overlying the semiconductor substrate and a gate structure overlying the dielectric layer. The device also has a channel region within a portion of the semiconductor substrate within a vicinity of the gate structure and a lightly doped source/drain regions in the semiconductor substrate to from diffused pocket regions underlying portions of the gate structure. The device has sidewall spacers on edges of the gate structure. The device also has an etched source region and an etched drain region. Each of the first source region and the first drain region is characterized by a recessed region having substantially vertical walls, a bottom region, and rounded corner regions connecting the vertical walls to the bottom region.

### CROSS-REFERENCES TO RELATED APPLICATIONS

This application claims priority to Chinese Application No.200710036768.4; filed on Jan. 19, 2007; commonly assigned, and of which is hereby incorporated by reference for all purposes.

### BACKGROUND OF THE INVENTION

The present invention is directed to integrated circuits and their processing for the manufacture of semiconductor devices. More particularly, the invention provides a method and structures for manufacturing MOS devices using strained silicon structures for advanced CMOS integrated circuit devices. But it would be recognized that the invention has a much broader range of applicability.

Integrated circuits have evolved from a handful of interconnected devices fabricated on a single chip of silicon to millions of devices. Conventional integrated circuits provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of integrated circuits.

Increasing circuit density has not only improved the complexity and performance of integrated circuits but has also provided lower cost parts to the consumer. An integrated circuit or chip fabrication facility can cost hundreds of millions, or even billions, of U.S. dollars. Each fabrication facility will have a certain throughput of wafers, and each wafer will have a certain number of integrated circuits on it. Therefore, by making the individual devices of an integrated circuit smaller, more devices may be fabricated on each wafer, thus increasing the output of the fabrication facility. Making devices smaller is very challenging, as each process used in integrated fabrication has a limit. That is to say, a given process typically only works down to a certain feature size, and then either the process or the device layout needs to be changed. Additionally, as devices require faster and faster designs, process limitations exist with certain conventional processes and materials.

An example of such a process is the manufacture of MOS devices itself. Such device has traditionally became smaller and smaller and produced faster switching speeds. Although there have been significant improvements, such device designs still have many limitations. As merely an example, these designs must become smaller and smaller but still provide clear signals for switching, which become more difficult as the device becomes smaller. Additionally, these designs are often difficult to manufacture and generally require complex manufacturing processes and structures. These and other limitations will be described in further detail throughout the present specification and more particularly below.

From the above, it is seen that an improved technique for processing semiconductor devices is desired.

### BRIEF SUMMARY OF THE INVENTION

According to the present invention, techniques for processing integrated circuits for the manufacture of semiconductor devices are provided. More particularly, the invention provides a method and structures for manufacturing MOS devices using strained silicon structures for CMOS advanced integrated circuit devices. But it would be recognized that the invention has a much broader range of applicability.

In a specific embodiment, the present invention provides a method for forming a semiconductor wafer, such as those for CMOS integrated circuits, and others. The method includes providing a semiconductor substrate, e.g., silicon wafer. The method forms a dielectric layer (e.g., oxide, nitride, oxynitride) overlying the semiconductor substrate. The method includes forming a gate layer overlying the dielectric layer and patterning the gate layer to form a gate structure including edges, Preferably, the gate structure is formed overlying a channel region. The method includes implanting lightly doped source/drain regions into the semiconductor substrate and heat treating the lightly doped source/drain regions to form diffused pocket regions underlying portions of the gate region. The method forms a dielectric layer overlying the gate structure to protect the gate structure including the edges and patterns the dielectric layer to form sidewall spacers on the gate structure. The method includes a multi-step etching process. The method includes anisotropic etching a source region and a drain region adjacent to the gate structure using the dielectric layer as a protective layer to form a first source region and a first drain region. Each of the first source region and the first drain region is characterized by a recessed region having substantially vertical walls, a bottom region, and sharp corners connecting the vertical walls to the bottom region. The method performs isotropic etching the source region and the drain region to cause a change of the sharp corner regions to rounded corner regions connected to the bottom region of each of the source and drain regions and to cause an undercut region within a vicinity of the channel region. The method deposits silicon germanium material into the source region and the drain region to fill the etched source region and the etched drain region. The method causing the channel region between the source region and the drain region to be strained in compressive mode from at least the silicon germanium material formed in the source region and the drain region.

In an alternative specific embodiment, the present invention provides yet an alternative method for forming a semiconductor integrated circuit. The method includes providing a semiconductor substrate and forming a dielectric layer overlying the semiconductor substrate. The method includes forming a gate layer overlying the dielectric layer and patterning the gate layer to form a gate structure including edges. Preferably, the gate structure is formed overlying a channel region. The method includes implanting lightly doped source/drain regions into the semiconductor substrate and heat treating the lightly doped source/drain regions to form diffused pocket regions underlying portions of the gate structure. The method forms a dielectric layer overlying the gate structure to protect the gate structure including the edges and patterning the dielectric layer to form sidewall spacers on the gate structure. The method performs anisotropic etching a source region and a drain region adjacent to the gate structure using the dielectric layer as a protective layer to form a first source region and a first drain region. Each of the first source region and the first drain region is characterized by a recessed region having substantially vertical walls, a bottom region, and sharp corners connecting the vertical walls to the bottom region. The method then isotropically etches the source region and the drain region to cause a change of the sharp corner regions to rounded corner regions connected to the bottom region of each of the source and drain regions and to cause an undercut region within a vicinity of the channel region. Preferably, the rounded corner regions have a radius of curvature of more than a couple of nanometers. The method maintains the etched surfaces during the isotropic etching free from any damage associated with an anisotropic etching process and deposits silicon germanium material into the source region and the drain region to fill the etched source region and the etched drain region. The method causes the channel region between the source region and the drain region to be strained in compressive mode from at least the silicon germanium material formed in the source region and the drain region.

In yet an alternative specific embodiment, the present invention provides a semiconductor integrated circuit device comprising a semiconductor substrate, e.g., silicon wafer, silicon on insulator. The device has a dielectric layer overlying the semiconductor substrate and a gate structure overlying the dielectric layer. The device also has a channel region within a portion of the semiconductor substrate within a vicinity of the gate structure and a lightly doped source/drain regions in the semiconductor substrate to from diffused pocket regions underlying portions of the gate structure. The device has sidewall spacers on edges of the gate structure. The device also has an etched source region and an etched drain region. Each of the first source region and the first drain region is characterized by a recessed region having substantially vertical walls, a bottom region, and rounded corner regions connecting the vertical walls to the bottom region. An undercut region is underlying a portion of the gate structure and within a vicinity of the channel region. The undercut region is within each of the recessed regions. Preferably, the device has a radius of curvature of more than a couple of nanometers characterizing the rounded corner regions. The device has one or more exposed surfaces of the recessed region being free from any damage associated with an anisotropic etching process. A silicon germanium material is formed into the source region and the drain region to fill the etched source region and the etched drain region. A strained region characterizing the channel region is between the source region and the drain region. Preferably, the strained region is in a compressive mode from at least the silicon germanium material formed in the source region and the drain region.

In a specific embodiment, the present invention provides a method using a silicon germanium fill material, which has a larger lattice spacing than single crystal silicon material. Such larger lattice spacing of silicon germanium fill material causes a channel region of an MOS transistor to be in a slightly compressive mode, when such material has been deposited in recessed regions adjacent to the channel region. Although the lattice spacing is slightly larger, silicon germanium still grows within the recessed regions, which are substantially single crystal silicon bearing material. Of course, there may be other variations, medications, and alternatives.

Many benefits are achieved by way of the present invention over conventional techniques. For example, the present technique provides an easy to use process that relies upon conventional technology. In some embodiments, the method provides higher device yields in dies per wafer. Additionally, the method provides a process that is compatible with conventional process technology without substantial modifications to conventional equipment and processes. Preferably, the invention provides for an improved process integration for design rules of 65 nanometers and less or 90 nanometers and less. Additionally, the invention provides for increased mobility of holes using a strained silicon structure for CMOS devices. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIGS. 1 through 5 are simplified cross-sectional view diagram of a method for fabricating a CMOS device according to an embodiment of the present invention.

### DETAILED DESCRIPTION OF THE INVENTION

According to embodiments of the present invention, techniques for processing integrated circuits for the manufacture of semiconductor devices are provided. More particularly, the invention provides a method and structures for manufacturing MOS devices using strained silicon structures for advanced CMOS integrated circuit devices. But it would be recognized that the invention has a much broader range of applicability.

A method for fabricating an integrated circuit device according to an embodiment of the present invention may be outlined as follows:

1. Provide a semiconductor substrate, e.g., silicon wafer, silicon on insulator;

2. Form a dielectric layer (e.g., gate oxide or nitride) overlying the semiconductor substrate;

3. Form a gate layer (e.g., polysilicon, metal) overlying the dielectric layer;

4. Pattern the gate layer to form a gate structure including edges (e.g., a plurality of sides or edges);

5. Form a dielectric layer overlying the gate structure to protect the gate structure including the edges;

6. Pattern the dielectric layer to form sidewall spacers on edges of the gate structure;

7. Perform an anisotropic etch process to form a source region and a drain region in the semiconductor substrate adjacent to the gate structure using the dielectric layer as a protective layer;

8. Perform an isotropic etch process on the source region and the drain region adjacent to the gate structure using the dielectric layer as the protective layer;

9. Deposit silicon germanium material into the source region and the drain region to fill the etched source region and the etched drain region;

10. Cause a channel region between the source region and the drain region to be strained in compressive mode from at least the silicon germanium material formed in the source region and the drain region, wherein the channel region is about the same width as the patterned gate layer;

11. Form sidewall spacers overlying the patterned gate layer; and

12. Perform other steps, as desired.

The above sequence of steps provides a method according to an embodiment of the present invention. As shown, the method uses a combination of steps including a way of forming an integrated circuit device such as an N-type channel device for a CMOS integrated circuit. The source/drain regions are formed using anisotropic and isotropic etching techniques, and the like. Other alternatives can also be provided where steps are added, one or more steps are removed, or one or more steps are provided in a different sequence without departing from the scope of the claims herein. Further details of the present method can be found throughout the present specification and more particularly below.

A method for fabricating a CMOS integrated circuit device according to an alternative embodiment of the present invention may be outlined as follows:

1. Provide a semiconductor substrate, e.g., silicon wafer, silicon on insulator;

2. Form a gate dielectric layer overlying the surface of the substrate;

3. Form a gate layer overlying the semiconductor substrate;

4. Pattern the gate layer to form an NMOS gate structure including edges and pattern a PMOS gate structure including edges;

5. Form a dielectric layer overlying the NMOS gate structure to protect the NMOS gate structure including the edges and overlying the PMOS gate structure to protect the PMOS gate structure including the edges;

6. Simultaneously etch using anisotropic techniques and isotropic techniques a first source region and a first drain region adjacent to the NMOS gate structure and etch a second source region and a second drain region adjacent to the PMOS gate structure using the dielectric layer as a protective layer;

7. Pretreat etched source/drain regions;

8. Mask NMOS regions;

9. Deposit silicon germanium material into the first source region and the first drain region to cause a channel region between the first source region and the first drain region of the PMOS gate structure to be strained in a compressive mode;

10. Strip Mask from NMOS regions;

11. Mask PMOS regions;

12. Deposit silicon carbide material into the second source region and second drain region to cause the channel region between the second source region and the second drain region of the NMOS gate structure to be strained in a tensile mode;

13. Perform other steps, as desired.

The above sequence of steps provides a method according to an embodiment of the present invention. As shown, the method uses a combination of steps including a way of forming a CMOS integrated circuit device. Other alternatives can also be provided where steps are added, one or more steps are removed, or one or more steps are provided in a different sequence without departing from the scope of the claims herein. Further details of the present method can be found throughout the present specification and more particularly below.

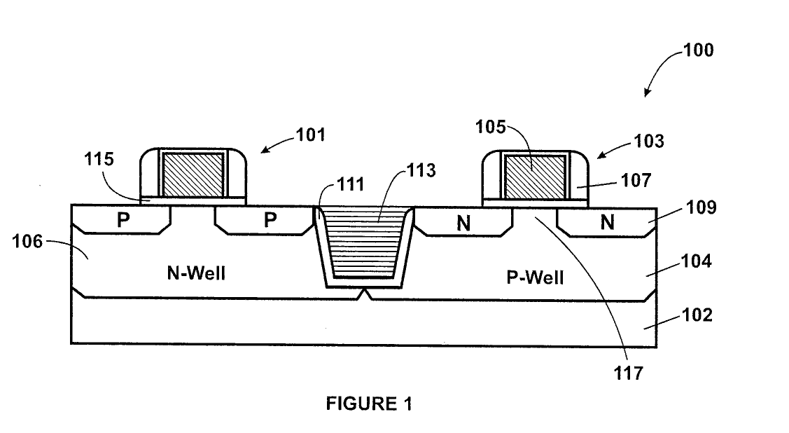

FIGS. 1 through 5 are simplified cross-sectional view diagrams of a method for fabricating a CMOS device according to an embodiment of the present invention. These diagrams are merely examples, which should not unduly limit the scope of the claims herein. One of ordinary skill in the art would recognize many variations, alternatives, and modifications. In a specific embodiment, the present invention provides a method for forming a semiconductor wafer, such as those for CMOS integrated circuits, and others. As shown, the method includes providing a semiconductor substrate 102, e.g., silicon wafer, silicon on insulator. The substrate includes N-type 106 and P-type 104 well regions, which are formed in the substrate. The substrate also includes isolation region 113. In a specific embodiment, the isolation region can include trench isolation with liner 111 or other forms of isolation techniques. Referring again to FIG. 1, which is directed to a CMOS integrated circuit, the substrate includes P-channel 101 and N-channel 103 devices. Of course, there can be other variations, modifications, and alternatives.

The method forms a gate dielectric layer 115 (e.g., oxide, nitride, oxynitride) overlying the semiconductor substrate. The gate dielectric layer acts as a gate insulating layer, which has a thickness of less than 40 Angstroms or even less than 10 Angstroms according to a specific embodiment. The method includes forming a gate layer 105 overlying the dielectric layer and patterning the gate layer to form a gate structure including edges, Preferably, the gate structure is formed overlying a channel region 117. In a specific embodiment, the gate layer can be formed using a polysilicon layer, which has been in-situ doped or diffused using a boron bearing impurity or other suitable species. In a specific embodiment, the channel region has a length of 90 nanometers or less or more preferably 65 nanometers or less.

Referring again to FIG. 1, the method forms a dielectric layer 107 overlying the gate structure to protect the gate structure including the edges and patterns the dielectric layer to form sidewall spacers on the gate structure. The dielectric layer can be any suitable material including silicon dioxide, silicon nitride, and other combination of these. The method uses the sidewall spacers and any overlying dielectric layer as a hard mask for a subsequent etching process of the source/drain regions into the semiconductor substrate. The method also includes implanting lightly doped source/drain regions 109 into the semiconductor substrate. Of course, one of ordinary skill in the art would recognize other variations, modifications, and alternatives.

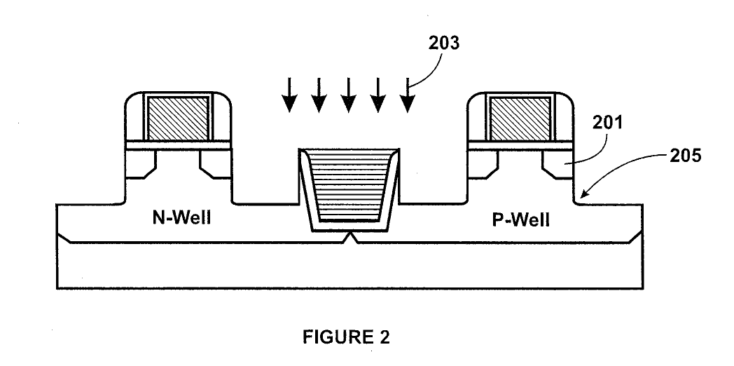

Referring now to FIG. 2, the method includes heat treating the lightly doped source/drain regions to form diffused pocket regions 201 underlying portions of the gate region. As shown in FIG. 2, the method includes a multi-step etching process according to a specific embodiment. The method includes anisotropic etching 203 a source region and a drain region adjacent to the gate structure using the dielectric layer as a protective layer to form a first source region and a first drain region. Each of the first source region and the first drain region is characterized by a recessed region having substantially vertical walls, a bottom region, and sharp corners 205 connecting the vertical walls to the bottom region. In a specific embodiment, the anisotropic etching uses a plasma etcher using a fluorine or chlorine bearing species at a pressure of 5 to 50 m Torr.

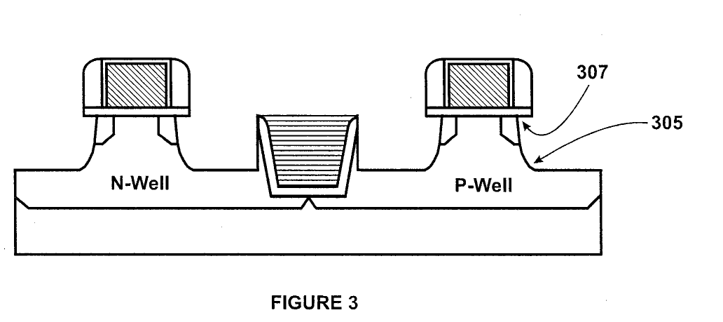

Referring to FIG. 3, the method performs isotropic etching the source region and the drain region to cause a change of the sharp corner regions to rounded corner regions 305 connected to the bottom region of each of the source and drain regions according to a specific embodiment. The isotropic etching can also cause an undercut region 307 within a vicinity of the channel region 307, which has been reduced in length according to a specific embodiment. In a specific embodiment, the sharp corners have a radius of curvature of a couple of Angstroms and less. The rounded corner regions have a radius of curvature of a couple of nanometers and less or more than a couple of nanometers according to a specific embodiment. Preferably, the etched surfaces after isotropic etching is substantially free from any surface damage caused by anisotropic etching. The damage free surface is desirable for forming single crystal silicon germanium within the recessed regions, as will be described in more detail below. In a specific embodiment, the isotropic etching occurs using a wet and/or dry etching technique. The wet etching technique uses chemical liquid and the dry etching techniques uses fluorine or chlorine plasmas according to a specific embodiment.

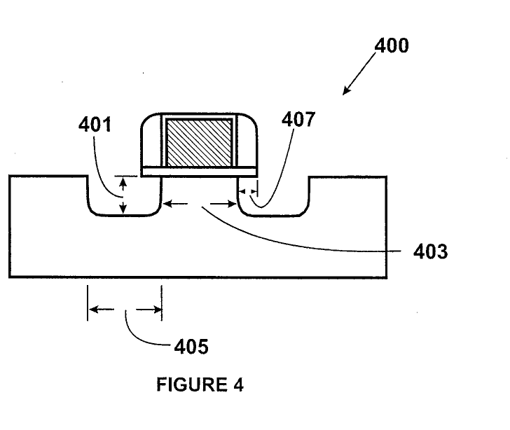

Referring to FIG. 4, the method forms a resulting etched MOS transistor structure 400 according to a specific embodiment. According to a specific embodiment, the etched source drain regions can include a depth 401 of about 5000 to 10,000 Angstroms or about 8,000 Angstroms. A channel width 403 can be 65 nanometers or less according to a specific embodiment. A length 405 of the source/drain region can be about 0.3 micrometers or other dimensions depending upon the specific embodiment. The undercut region can have a size 407 of about 10 Angstroms to about 20 Angstroms or less than 20 Angstroms according to a specific embodiment. Of course, there can be other variations, modifications, and variations.

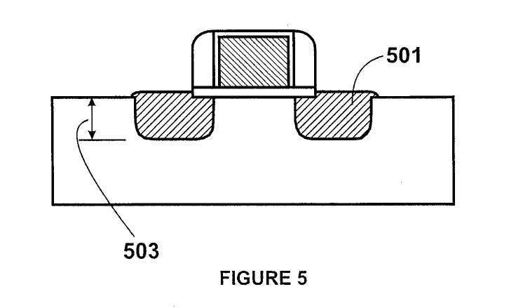

The method deposits silicon germanium material 501 into the etched source region and the etched drain region to fill the etched source region and the etched drain region as illustrated by FIG. 5. The silicon germanium is provided in an epitaxial reactor, which selectively deposits the silicon germanium only on exposed surfaces of single crystal silicon material, although other techniques can be used. Preferably, the method causing the channel region between the source region and the drain region to be strained in a compressive mode from at least the silicon germanium material formed in the source region and the drain region. The strain occurs, in part, from the larger lattice constant of the silicon germanium material, which has a composition of silicon to germanium of 10% to 40% according to a specific embodiment. In a preferred embodiment, the compressive mode increases a mobility of holes in the channel region although other influences could also exist. In a specific embodiment, the silicon germanium material fills the etched source region and the etched drain region, which has a depth 503 of about 8000 Angstrom respectively. Of course, one of ordinary skill in the art would recognize many variations, modifications, and alternatives.

To complete the device, there can be other processing steps such as formation of interlayer dielectric layers, metal layers, passivation layers, implanting, and any combination of these. The above sequence of steps provides a method according to an embodiment of the present invention. As shown, the method uses a combination of steps including a way of forming a CMOS integrated circuit device. Other alternatives can also be provided where steps are added, one or more steps are removed, or one or more steps are provided in a different sequence without departing from the scope of the claims herein.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for forming a CMOS semiconductor wafer comprising:
providing a semiconductor substrate;
forming a dielectric layer overlying the semiconductor substrate;
forming a gate layer overlying the dielectric layer;
patterning the gate layer to form a gate structure including edges, the gate structure being formed overlying a channel region;
implanting lightly doped source/drain regions into the semiconductor substrate;
heat treating the lightly doped source/drain regions to form diffused pocket regions underlying portions of the gate region;
forming a dielectric layer overlying the gate structure to protect the gate structure including the edges;
patterning the dielectric layer to form sidewall spacers on the gate structure;
anisotropic etching a source region and a drain region adjacent to the gate structure using the dielectric layer as a protective layer to form a first source region and a first drain region, each of the first source region and the first drain region being characterized by a recessed region having substantially vertical walls, a bottom region, and sharp corners connecting the vertical walls to the bottom region;
isotropic etching the source region and the drain region to cause a change of the sharp corner regions to rounded corner regions connected to the bottom region of each of the source and drain regions and to cause an undercut region within a vicinity of the channel region;
depositing silicon germanium material into the source region and the drain region to fill the etched source region and the etched drain region; and
causing the channel region between the source region and the drain region to be strained in compressive mode from at least the silicon germanium material formed in the source region and the drain region.

2. The method of claim 1 wherein the dielectric layer is less than 300 Angstroms.

3. The method of claim 1 wherein the channel region has an effective length less than a width of the gate structure.

4. The method of claim 1 wherein the semiconductor substrate is essential silicon material.

5. The method of claim 1 wherein the silicon germanium material is crystalline.

6. The method of claim 1 wherein the silicon germanium has a ratio of silicon/germanium of 10% to 30%.

7. The method of claim 1 wherein the depositing is provided using an epitaxial reactor.

8. The method of claim 1 wherein the compressive mode increases a mobility of holes in the channel region.

9. The method of claim 1 wherein the anisotropic etching comprises plasma etching or reactive ion etching.

10. The method of claim 1 wherein the isotropic etching comprises wet etching or plasma etching.

11. The method of claim 10 wherein the isotropic etching uses a fluorine or chlorine bearing species.

12. The method of claim 1 wherein the isotropic etching comprises dry etching.

13. The method of claim 1 wherein the channel region is 65 nanometers and less.

14. The method of claim 1 wherein the depositing is an isotropic epi deposition process to selectively grow silicon germanium material on exposed silicon regions.

15. The method of claim 1 wherein the sharp corners have a radius of curvature of a couple of Angstroms and less.

16. The method of claim 1 wherein the rounded corner regions have a radius of curvature of a few nanometers and less.

17. The method of claim 1 wherein the etched surfaces after isotropic etching is substantially free from any surface damage caused by anisotropic etching.

18. A method for forming a semiconductor integrated circuit comprising:
providing a semiconductor substrate;
forming a dielectric layer overlying the semiconductor substrate;
forming a gate layer overlying the dielectric layer;
patterning the gate layer to form a gate structure including edges, the gate structure being formed overlying a channel region;
implanting lightly doped source/drain regions into the semiconductor substrate;
heat treating the lightly doped source/drain regions to form diffused pocket regions underlying portions of the gate structure;
forming a dielectric layer overlying the gate structure to protect the gate structure including the edges;
patterning the dielectric layer to form sidewall spacers on the gate structure;
anisotropic etching a source region and a drain region adjacent to the gate structure using the dielectric layer as a protective layer to form a first source region and a first drain region, each of the first source region and the first drain region being characterized by a recessed region having substantially vertical walls, a bottom region, and sharp corners connecting the vertical walls to the bottom region;
isotropic etching the source region and the drain region to cause a change of the sharp corner regions to rounded corner regions connected to the bottom region of each of the source and drain regions and to cause an undercut region within a vicinity of the channel region, the rounded corner regions having a radius of curvature of more than a few nanometers.
maintaining the etched surfaces during the isotropic etching free from any damage associated with an anisotropic etching process;
depositing silicon germanium material into the source region and the drain region to fill the etched source region and the etched drain region; and
causing the channel region between the source region and the drain region to be strained in compressive mode from at least the silicon germanium material formed in the source region and the drain region.

19. A semiconductor integrated circuit device comprising:
a semiconductor substrate;
a dielectric layer overlying the semiconductor substrate;
a gate structure overlying the dielectric layer;
a channel region within a portion of the semiconductor substrate within a vicinity of the gate structure;
a lightly doped source/drain regions in the semiconductor substrate to from diffused pocket regions underlying portions of the gate structure;
sidewall spacers on edges of the gate structure;
an etched source region and an etched drain region, each of the first source region and the first drain region being characterized by a recessed region having substantially vertical walls, a bottom region, and rounded corner regions connecting the vertical walls to the bottom region;
an undercut region underlying a portion of the gate structure and within a vicinity of the channel region, the undercut region being within each of the recessed regions;
a radius of curvature of more than a few nanometers characterizing the rounded corner regions;
one or more exposed surfaces of the recessed region being free from any damage associated with an anisotropic etching process;
a silicon germanium material formed into the source region and the drain region to fill the etched source region and the etched drain region; and
a strained region characterizing the channel region between the source region and the drain region, the strained region being in a compressive mode from at least the silicon germanium material formed in the source region and the drain region.

20. The semiconductor integrated circuit device of claim 19 wherein the channel region has a length of less than 65 nanometers.
